(19) United States
(12) Patent Application Publication
(10) Pub. No.: US 2025/0200249 A1
(43) Pub. Date: Jun. 19, 2025

(54) NEURAL NETWORK BASED DISCRETE ELEMENT CONTACT MODEL FOR PREDICTING MECHANICAL BEHAVIOR OF AGRICULTURAL MATERIALS

(71) Applicant: Deere & Company, Moline, IL (US)

(72) Inventors: Adam Kovacs, Homburg (DE); Donald Harby, Illinois City, IL (US); Christopher C. Relander, Matherville, IL (US); Zachary A. Wymore, Moline, IL (US)

(21) Appl. No.: 18/545,473

(22) Filed: Dec. 19, 2023

(51) Int. Cl. G06F 30/27; G06N 3/0499; G06N 3/0985

(52) U.S. Cl. CPC G06F 30/27; G06N 3/0499; G06N 3/0985

(57) ABSTRACT

A system and method are provided for predicting mechanical behavior of agricultural materials, utilizing neural network-based discrete element method (DEM) models. Test datasets are provided corresponding to observed conditions of respective agricultural materials, for training the neural network which is configured according to predetermined formulations of DEM models identified for a particular industrial process. Variables for contact model parameters are generated during the training as best correlating the test dataset with an observed mechanical behavior of the agricultural materials under the observed conditions. Upon receiving a current input dataset for simulation of the industrial process, the identified DEM model is applied with the generated variables for empirically associating the current input dataset with at least one predicted mechanical behavior, and output signals are generated corresponding to the predicted mechanical behavior within at least a partial simulation of the industrial process.

### FIELD OF THE DISCLOSURE

The present disclosure relates generally to the prediction of mechanical behavior in particles under known conditions. More particularly, certain embodiments according to the present disclosure relate to a neural network-based discrete element contact model for predicting the mechanical behavior of agricultural materials.

### BACKGROUND

An understanding of the collective mechanical behavior of granular agricultural materials is of substantial interest when, for example, designing enclosures for loading or otherwise containing such materials, designing of machines or planning operations of machines for the handling or working of such materials, and the like. Referring to work machines and associated implements for working, loading/unloading, or transporting such materials, for example, the mechanical behavior under various conditions may be relevant to work machine performance with respect to efficiency, productivity, reliability, etc., and models for simulating material interactions with machine equipment are accordingly important for product development.

Discrete Element Modeling (DEM) is a known tool for predicting the behaviors of certain agricultural materials, particularly with respect to the monitoring or modeling of individual particle movement, including multidimensional space interactions between such particles and work machine components. Recent advances have been made in the field of discrete element contact modeling generally, but conventional examples of such systems are still not broadly implemented for predicting collective mechanical behavior of agricultural materials, for example in response to forces applied through interactions with machinery or in contact with other boundary forces, due at least in in part to computational complexity, limited accuracy, limited constitutive flexibility, etc.

### BRIEF SUMMARY

The current disclosure provides an enhancement to conventional systems and methods, at least in part by introducing a novel system and method for training, validating, and implementing a feed forward neural network-based discrete element contact model to predict governing material behavior based on the actual (e.g., observed) conditions of agricultural materials. By using systems and methods combining DEM and neural networks as disclosed herein, DEM simulations may be accelerated in nature relative to conventional techniques, and the accuracy of resulting agricultural material models can be increased significantly, which is a factor of particular importance for product development and validation in virtual environments.

In one embodiment, a computer-implemented method as disclosed herein comprises: identifying a discrete element method (DEM) model configured to perform simulations of mechanical behavior of one or more agricultural materials under one or more variable conditions in an industrial process having a predetermined formulation; obtaining test datasets, each test dataset corresponding to at least one of the one or more respective agricultural materials and at least one of the one or more variable conditions; training a neural network structure using the test datasets, wherein the neural network structure is configured according to the predetermined formulation of the identified DEM model and having one or more corresponding contact model parameters, wherein variables for the one or more contact model parameters are generated during the training as best correlating the test dataset with an observed mechanical behavior of the at least one of the one or more respective agricultural materials and the at least one of the one or more variable conditions; receiving a current input dataset for simulation of the industrial process, the current dataset comprising one or more agricultural materials and one or more corresponding conditions; applying the identified DEM model having the generated variables from the neural network structure to the current input dataset for empirically associating the current input dataset with at least one predicted mechanical behavior; and generating output signals corresponding to the predicted mechanical behavior within at least a partial simulation of the industrial process.

In an exemplary aspect according to the above-referenced method embodiment, each test dataset may be pre-processed and transformed, prior to training, according to the one or more contact model parameters. The neural network is accordingly configured based at least in part on the formulation of the identified DEM model, for example to facilitate subsequent coupling of the neural network with the DEM model.

In another exemplary aspect according to the above-referenced method embodiment, the variables for the one or more contact model parameters may be automatically selected by an optimizer during one or more iterations of the training as corresponding with minimized cross-validation losses.

In another exemplary aspect according to the above-referenced method embodiment, the neural network structure may comprise one or more hidden intermediate layers of neurons according to the predetermined formulation of the identified DEM model. The structure may take the form of a feed forward neural network.

In another exemplary aspect according to the above-referenced method embodiment, the trained neural network structure may further be validated at least in part through one or more virtual test iterations with respect to simulated mechanical behaviors for each layer, wherein validating the trained datasets comprises automated evaluation of results for the at least one virtual test iteration on a quantitative basis and a qualitative basis.

In another exemplary aspect according to the above-referenced method embodiment, an output for at least a first layer provides a predicted result for a subsequent connected layer.

In another exemplary aspect according to the above-referenced method embodiment, the conditions include physical properties, which may for example and without limitation include one or more of: moisture content; maturity; conductivity; and temperature.

In another exemplary aspect according to the above-referenced method embodiment, the conditions include mechanical properties, which may for example and without limitation include stiffness and/or strength.

In another exemplary aspect according to the above-referenced method embodiment, the conditions may include historical external loads and current external loads on the one or more agricultural materials.

In another exemplary aspect according to the above-referenced method embodiment, the industrial process being simulated corresponds to one or more components of a work machine interacting with the one or more agricultural materials. For example and without limitation, the neural-network based DEM model may be implemented to simulate mechanical behavior of agricultural materials in response to external forces such as provided by an excavator blade in a worksite being excavated, mechanical behavior of agricultural materials filling within a bucket or truck bin after loading thereof, mechanical behavior of agricultural materials in a field being tilled, etc.

In another exemplary aspect according to the above-referenced method embodiment, the output signals may be provided as inputs to a model associated with virtual design of the one or more work machine components for working and/or storing the one or more agricultural materials.

In another exemplary aspect according to the above-referenced method embodiment, the outputs may be provided as inputs to a model associated with planning and/or control of operations for the one or more work machine components in a worksite comprising the one or more agricultural materials.

In another embodiment, a system as disclosed herein may include one or more non-transitory computer-readable media having instructions residing thereon, and one or more processors configured to execute the instructions and thereby direct the performance of operations according to the above-referenced method embodiment and optionally one or more further aspects as described with respect thereto.

Numerous objects, features and advantages of the embodiments set forth herein will be readily apparent to those skilled in the art upon reading of the following disclosure when taken in conjunction with the accompanying drawings.

### BRIEF DESCRIPTION OF THE DRAWINGS

FIG. 1 is a block diagram representing an embodiment of a system as disclosed herein.

FIG. 2 is a block diagram representing an embodiment of a feed-forward neural network as disclosed herein.

FIG. 3 is a flowchart representing an embodiment of a method for predicting mechanical behavior of agricultural materials as disclosed herein.

### DETAILED DESCRIPTION

The implementations disclosed in the above drawings and the following detailed description are not intended to be exhaustive or to limit the present disclosure to these implementations. Any alterations and further modifications to the described devices, systems, methods, and any further application of the principles of the present disclosure are fully contemplated as would normally occur to one skilled in the art to which the disclosure relates. In particular, it is fully contemplated that the features, components, steps, or a combination thereof described with respect to one example may be combined with the features, components, steps, or a combination thereof described with respect to other examples of the present disclosure.

Systems and methods in various embodiments according to the present disclosure relate to a neural network-based discrete element contact model for predicting the mechanical behavior of agricultural materials, for example dynamic behavior of such materials of various sizes in response to external forces and under various relevant conditions.

Examples of such agricultural materials may include granular materials such as soil, clay, rock, and the like, as well as any of various crop types, grains, etc.

Accurate prediction of mechanical behavior of such agricultural materials, in association with various observed or otherwise determined conditions such as for example physical properties, mechanical properties, loading, and the like, may be used for the design, product development, and validation of equipment for working, shaping, storing, transporting, etc., such materials.

Exemplary equipment in this context may include work machines such as excavators, harvesters, graders, loaders, road construction machines, and the like, as well as associated work implements or attachments for engaging or traveling across the agricultural materials in various contexts. Further exemplary equipment may include enclosures such as loading containers, buckets, hoppers, truck bins, grain silos, and the like.

DEM software modules are known in the art for simulating industrial applications as may be associated with various combinations of the above-referenced agricultural materials, work machines, equipment, etc. As but one of many potential examples, a work machine such as an excavator or crawler dozer may include a bucket for receiving and selectively discharging material, and a blade at one end of the bucket for engaging and working the ground surface. For example, various DEM software modules are known in the art for simulating the filling of a bucket with agricultural material under specified conditions (e.g., type, size, shape, moisture level of the material), or for simulating the interaction of a blade with a ground surface formed of agricultural material under specified conditions.

However, it is typical using conventional tools for DEM simulations to be limited in scope, such as two-dimensional simulations or limited temporally or spatially, to account for the excessive computational requirements in accurately modeling the mechanical behavior of the agricultural materials, particularly when considering the respective interactions with external forces, relevant conditions, etc.

Various embodiments of an invention may remove such limitations by coupling a feed forward neural network structure to a DEM simulation module, even in some embodiments an otherwise previously known DEM software and associated formulations for a selected industrial process, to rapidly generate predicted mechanical behavior for the underlying agricultural materials.

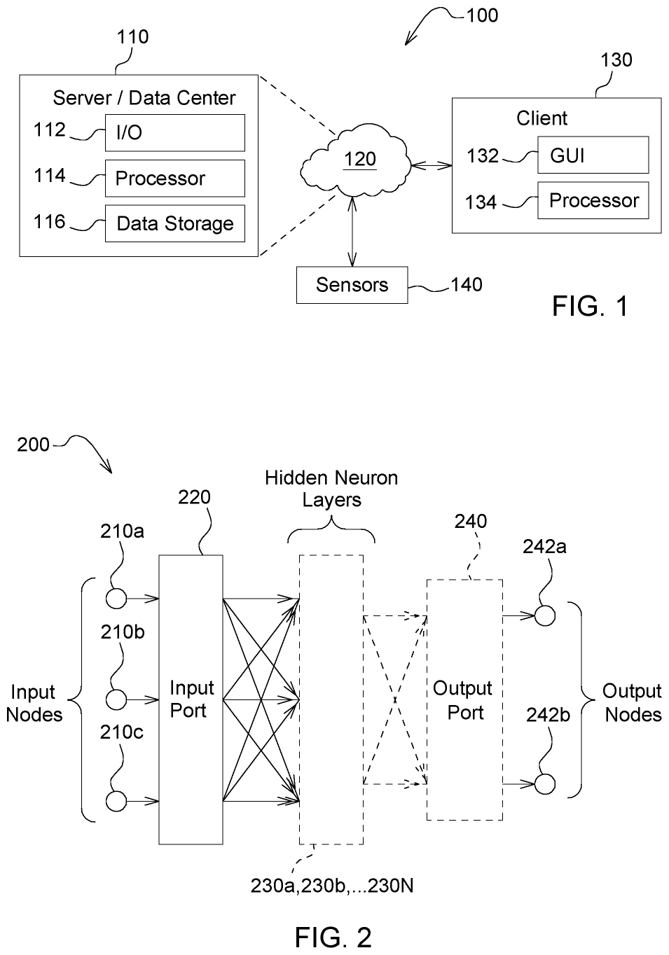

An embodiment of a system 100 as illustrated in FIG. 1 includes a first computing device 110, for example a data center, server network, or the like, including input/output devices 112, one or more processors 114 functionally linked, selectively or continuously, to data storage 116 associated with the first computing device 110, and in various embodiments to various second (client) computing devices 130 via a communications network 120. Client computing devices 130 may include respective user interfaces 132 and processors 134, as well as local data storage and input/output devices (not shown). The first and/or second computing devices 110, 130 may further be linked to one or more sensors 140 for providing input data relating to the models as further described herein.

The components of a system 100 as disclosed herein, and more particularly a computing unit 110, 130 and associated program modules or the like as configured to execute steps in a method 300 as further described below, may generally be programmed to request, extract, receive, translate, ingest, and otherwise process data from input/output devices 112, user interfaces 132, sensors 140, work machines, laboratory equipment, remote/third party devices, or the like via manual upload, application program interfaces, etc. Types and formats of such data may be well understood by those of skill in the art, and user interfaces may for example be dynamically generated based on the type and/or format of data, a status of a user interacting with the respective computing unit via the interface, a type of computing device associated with the user, etc.

Sensors 140 for providing input data to models as disclosed herein, or for example configured to provide output signals representing particular characteristics of agricultural materials and which may be processed to identify the desired input data to models as disclosed herein, may in various embodiments include sensors mounted on mobile work machines or equipment, stationary sensors in a laboratory, online data gathering tools, and the like. Relevant input data for generating a test dataset in a specified industrial application may for example be received from a first set of sensors in a laboratory context and/or a second set of sensors in the field, such as mounted on a mobile work machine, whereas in various embodiments corresponding input data for generating a “new” dataset for which predictions are requested from a validated model may be received from the same or a different combination of sensors.

Exemplary such sensors 140 may include, without limitation unless otherwise specifically stated or implied for a particular industrial process to be simulated: imaging devices such as cameras, laser scanners, or lidar sensors; position sensors which generate outputs corresponding to a location, orientation, or pose of a work machine; environmental sensors for measuring temperature, moisture, and the like; sensors which generate outputs corresponding to different types of agricultural material properties, such as crop type, characteristics of the crop as they are being processed, and the like.

Where multiple processors 114 are implemented by a first computing device 110 or network of computing devices 110, one or more of the processors 114 may be local, remote, or a mixture thereof. One or more of the processors 114 may share information via wired, wireless, or a mixture of communications means. One or more processors 114 may fixedly or dynamically assign portions of computation with respect to functions as described herein to one or more other processors of the computing device.

The term “processor” as used herein may refer to at least general-purpose or specific-purpose processing devices and/or logic as may be understood by one of skill in the art, including but not limited to a microprocessor, a microcontroller, a state machine, and the like. A processor can also be implemented as a combination of computing devices, e.g., a combination of a DSP and a microprocessor, a plurality of microprocessors, one or more microprocessors in conjunction with a DSP core, or any other such configuration.

An input/output device 112 may refer to or otherwise include one or more devices as a part of a communication unit configured to support or provide communications between the first computing device 110 and external sensors, systems, and/or devices, and/or support or provide communication interface with respect to internal components of the first computing device. The communication unit may include wireless communication logic and system components (e.g., via cellular modem, WiFi, Bluetooth, or the like) and/or may include one or more wired communications terminals such as universal serial bus ports. In various embodiments, the communication unit may communicate over a controller area network (CAN) bus (or another network, such as an Ethernet network, etc.) to communicate information between one or more of the above-referenced elements.

The data storage 116 may, unless otherwise stated, generally encompass hardware such as volatile or non-volatile storage devices, drives, memory, or other storage media, as well as in some embodiments one or more databases residing thereon.

Where a computing device 110, 130 as referenced herein may be provided onboard a work machine or vehicle, the device itself and the associated inputs and outputs available for processing (locally or otherwise) may be dependent on the type of machine or vehicle. For example, different types of work machines may include work implements, traveling devices, sprayers, cameras, and other imaging and/or perception devices, etc., along with corresponding controllers.

While the computing device 110 may generally be referred to herein in the context of a server network or data center, in some embodiments processors 114 of the computing device 110 may relate to or otherwise include processors associated with mobile computing devices such as tablet computers, cell phones, or mobile work machines. In some examples, all or portions of computations may be performed by quantum computers.

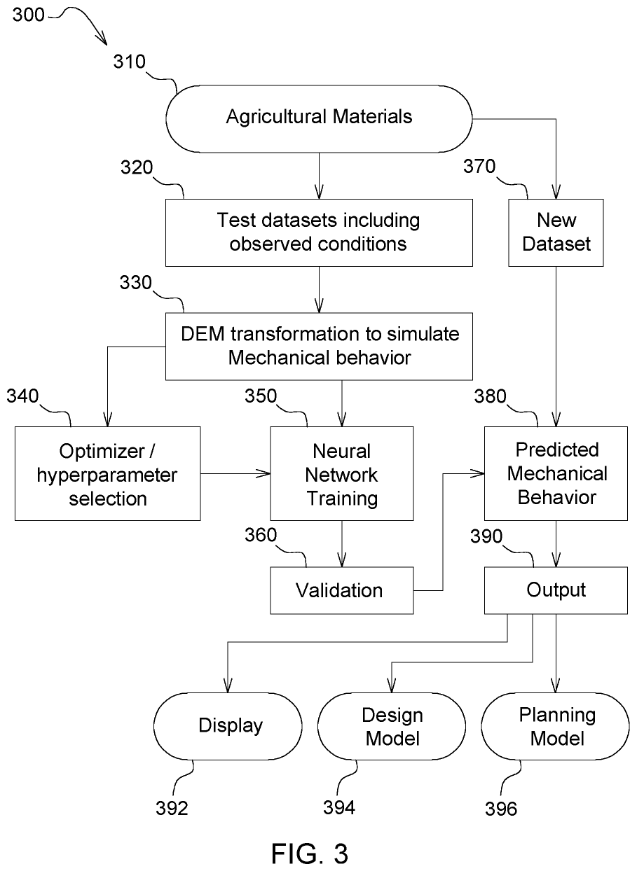

An exemplary embodiment of a method 300 as illustrated in FIG. 3 and further described below for modeling agricultural material behavior may for example be performed through implementation of the system 100 of FIG. 1, but is not limited to the same unless otherwise specifically noted. Various types of machine learning models and corresponding algorithms may be implemented with embodiments of a system and method as disclosed herein. In one exemplary embodiment as represented in FIG. 2, the system 100 and method 300 may utilize an exemplary discrete element contact model based in part on a feed forward neural network structure 200 including various input nodes 210 feeding an input port 220 which is connected to an output port 240 via one or more hidden layers of neurons 230a, 230b, . . . 230N and a discretized material continuum based on the discrete element method (DEM) formulation, or for example corresponding to parameters and/or specifications for a DEM software module that has been selected for simulating mechanical behavior in the desired industrial process.

While the illustrated model 200 in FIG. 2 includes three input nodes 210a, 210b, 210c with respect to the input port 220 and two output nodes 242a, 242b from the output port 240, it may be appreciated that more or fewer respective nodes may be present for various alternative embodiments of the model 200 in accordance with the present disclosure. Further, while more than one hidden layer of neurons 230 is shown in FIG. 2, it may be appreciated that in some embodiments only one layer is necessary, but additional layers may be selectively utilized.

One of skill in the art may further appreciate that alternative embodiments of the method 300 may include fewer or additional steps, and that certain disclosed steps may for example be performed in different chronological order or simultaneously. Generally stated, various operations, steps, or algorithms as described herein can be embodied directly in hardware, in a computer program product such as a software module executed by a processor, or in a combination of the two. The computer program product can reside in RAM memory, flash memory, ROM memory, EPROM memory, EEPROM memory, registers, hard disk, a removable disk, or any other form of computer-readable medium known in the art. An exemplary computer-readable medium can be coupled to the processor such that the processor can read information from, and write information to, the memory/storage medium. In the alternative, the medium can be integral to the processor, the processor and the medium can reside as discrete components in a user terminal, or the like.

The various illustrative logical blocks, modules, and algorithm steps described in connection with the embodiments disclosed herein can be implemented as electronic hardware, computer software, or combinations of both. To clearly illustrate this interchangeability of hardware and software, various illustrative components, blocks, modules, and steps are described generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

In various embodiments, the method 300 relates to a neural network-based discrete element contact model for predicting the mechanical behavior of agricultural materials based on measured or otherwise determined conditions (represented as inputs at step 310). Whereas relatively simple modeling can be applied in other contexts for individual material particles, a contact model as further discussed herein further models contact forces relating to collisions between the various material particles and their neighbors or an external boundary.

In one branch of the method 300 of FIG. 3, the model is trained using “test” datasets from inputs in step 310, whereas in a separate branch the trained and validated model is utilized for prediction based on “new” datasets. Training data for the neural network may for example be obtained from various laboratory and/or field tests depending on the processes that are employed on the agricultural material (step 320). The datasets may include one or more conditions observed or otherwise determined for each relevant type of agricultural material. Non-limiting examples of such conditions may include physical properties such as moisture content, maturity, conductivity, and/or temperature, mechanical properties such as stiffness and/or strength, historical and current external loads on the one or more agricultural materials, and the like.

Before training the neural network, the data may preferably be pre-processed and transformed to generate datasets according to predetermined or otherwise identified DEM formulations (step 330). Such DEM formulations may for example be dependent on the processes employed on the agricultural material, or otherwise selected to capture the expected range of behaviors. Various examples may include datasets corresponding to simulations of agricultural material of certain types and conditions when loaded within an enclosure, unloaded in piles or otherwise worked from a natural location within a worksite or field, in situ geomaterial within a worksite or field, etc.

The neural network may comprise a feed forward neural network 200 having a unidirectional but nonetheless nonlinear mapping structure. This structure may take the form of a multi-layer perceptron as known in the art, wherein information received at an input port 220 via input nodes 210 progresses forward through one or more intermediate hidden layers 230 to output nodes 242 via an output port 240. In an embodiment, the hidden layers 230 comprise one or more layers of artificial neurons each of which include one or more computational units or functions. An individual layer may for example receive its weighted inputs from respectively connected neurons of the previous layer, which may be aggregated along with a scaling bias unit for improved convergence properties.

Various embodiments of machine learning models as known in the art include variable governing parameters which are optimized during training to better simulate (or approximate in a particular simulation) observed real-life results corresponding to an input dataset, which as previously noted may include one or more agricultural materials and associated conditions. Such variables may comprise hyperparameters that may initially be set (e.g., user-specified) before training.

Tuning of the hyperparameters, or in other words optimizing the values therefor, follows during training to obtain a set of values for the hyperparameters corresponding to an accurate input-output mapping of the neural network for the training dataset. In various embodiments, tuning of parameters may be performed automatically during or between training iterations, manually based on user selection via a system interface, or combinations thereof.

In some embodiments the hyperparameters are not initially user-specified but instead predetermined formulaically or otherwise according to a “best guess” distribution of possible simulation parameters corresponding to a specified output array, and in some embodiments may initially be unknown and merely derived during training. The hyperparameters may for example determine aspects of the neural network structure and/or training parameters, such as the number of hidden neuron layers, number and/or definition of training steps, learning rates, batch size, and the like.

One or more loss functions may further be defined, separate from the hyperparameters themselves in many embodiments, but also important to a successful learning process in a neural network.

During training of the neural network (step 350), the hyperparameters for the neural network may accordingly be varied in order for the neural network output to align with the measured output of a known dataset, and in various embodiments the hyperparameters are preferably optimized through an optimization algorithm that minimizes cross-validation losses (step 340). Optimization algorithms are known for training of learning models with the purpose of error minimization, selection of which may in various embodiments be dependent for example on a desired learning rate and corresponding convergence characteristics, possibly at the expense of overall accuracy.

After the model is trained, for example when the neural network has been sufficiently trained wherein output predictions of material behavior best correlate to what is actually observed in response to the input dataset (e.g., materials and associated conditions), the neural network configuration may be at least temporarily defined and deployed into the discrete element software module for validation. To validate the material behavior predicted by the neural network-based model the same tests may be performed virtually and the results evaluated on qualitative and/or quantitative bases (step 360).

The validated model may subsequently be selectively retrieved and utilized against a new data set (received as an input in step 370) to accurately predict mechanical behavior of corresponding agricultural materials (step 380). An output from the model (in step 390) can accordingly be displayed to an authorized user via for example a user interface 132 of a client device 130 (step 392) or automatically provided as an input to further models for product development and/or validation in virtual environments. Exemplary inputs may be for an equipment design model (step 394), a planning model (step 396), or various equivalents and alternatives of models and software modules to utilize such information as may be appreciated by one of skill in the art.

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

As used herein, the phrase “one or more of,” when used with a list of items, means that different combinations of one or more of the items may be used and only one of each item in the list may be needed. For example, “one or more of” item A, item B, and item C may include, for example, without limitation, item A or item A and item B. This example also may include item A, item B, and item C, or item Band item C.

Thus, it is seen that the apparatus and methods of the present disclosure readily achieve the ends and advantages mentioned as well as those inherent therein. While certain preferred embodiments of the disclosure have been illustrated and described for present purposes, numerous changes in the arrangement and construction of parts and steps may be made by those skilled in the art, which changes are encompassed within the scope and spirit of the present disclosure as defined by the appended claims. Each disclosed feature or embodiment may be combined with any of the other disclosed features or embodiments.

What is claimed is:

1. A computer-implemented method of predicting mechanical behavior of agricultural materials, the method comprising:
identifying a discrete element method (DEM) model configured to perform simulations of mechanical behavior of one or more agricultural materials under one or more variable conditions in an industrial process having a predetermined formulation;
obtaining test datasets, each test dataset corresponding to at least one of the one or more respective agricultural materials and at least one of the one or more variable conditions;
training a neural network structure using the test datasets, wherein the neural network structure is configured according to the predetermined formulation of the identified DEM model and having one or more corresponding contact model parameters, wherein variables for the one or more contact model parameters are generated during the training as best correlating the test dataset with an observed mechanical behavior of the at least one of the one or more respective agricultural materials and the at least one of the one or more variable conditions;
receiving a current input dataset for simulation of the industrial process, the current dataset comprising one or more agricultural materials and one or more corresponding conditions;
applying the identified DEM model having the generated variables from the neural network structure to the current input dataset for empirically associating the current input dataset with at least one predicted mechanical behavior; and
generating output signals corresponding to the predicted mechanical behavior within at least a partial simulation of the industrial process.

2. The method of claim 1, comprising transforming each test dataset, prior to training, according to the one or more contact model parameters.

3. The method of claim 2, wherein the variables for the one or more contact model parameters are automatically selected by an optimizer during one or more iterations of the training as corresponding with minimized cross-validation losses.

4. The method of claim 2, wherein the neural network structure comprises a feed forward neural network having an input layer coupled to an output layer via one or more hidden intermediate layers of neurons according to the predetermined formulation of the identified DEM model.

5. The method of claim 4, further comprising validating the trained neural network structure through one or more virtual test iterations with respect to simulated mechanical behaviors for each layer, wherein validating the trained datasets comprises automated evaluation of results for the at least one virtual test iteration on a quantitative basis and a qualitative basis.

6. The method of claim 4, wherein an output for at least a first layer provides a predicted result for a subsequent connected layer.

7. The method of claim 1, wherein the conditions include physical properties comprising one or more of: moisture content; maturity; conductivity; and temperature.

8. The method of claim 1, wherein the conditions include mechanical properties comprising one or more of stiffness and strength.

9. The method of claim 1, wherein the conditions include historical and current external loads on the one or more agricultural materials.

10. The method of claim 1, wherein the industrial process being simulated corresponds to one or more components of a work machine interacting with the one or more agricultural materials.

11. The method of claim 10, wherein the output signals are provided as inputs to a model associated with virtual design of the one or more work machine components for working and/or storing the one or more agricultural materials.

12. The method of claim 10, wherein the outputs are provided as inputs to a model associated with planning and/or control of operations for the one or more work machine components in a worksite comprising the one or more agricultural materials.

13. A system comprising one or more non-transitory computer-readable media having instructions residing thereon, and one or more processors configured to execute the instructions and thereby direct the performance of operations comprising:
identifying a discrete element method (DEM) model configured to perform simulations of mechanical behavior of one or more agricultural materials under one or more variable conditions in an industrial process having a predetermined formulation;
obtaining test datasets, each test dataset corresponding to at least one of the one or more respective agricultural materials and at least one of the one or more variable conditions;
training a neural network structure using the test datasets, wherein the neural network structure is configured according to the predetermined formulation of the identified DEM model and having one or more corresponding contact model parameters, wherein variables for the one or more contact model parameters are generated during the training as best correlating the test dataset with an observed mechanical behavior of the at least one of the one or more respective agricultural materials and the at least one of the one or more variable conditions;
receiving a current input dataset for simulation of the industrial process, the current dataset comprising one or more agricultural materials and one or more corresponding conditions;
applying the identified DEM model having the generated variables from the neural network structure to the current input dataset for empirically associating the current input dataset with at least one predicted mechanical behavior; and
generating output signals corresponding to the predicted mechanical behavior within at least a partial simulation of the industrial process.

14. The system of claim 13, the one or more processors further configured to transform each test dataset, prior to training, according to the one or more contact model parameters.

15. The system of claim 14, wherein the variables for the one or more contact model parameters are automatically selected by an optimizer during one or more iterations of the training as corresponding with minimized cross-validation losses.

16. The system of claim 14, wherein the neural network structure comprises a feed forward neural network having an input layer coupled to an output layer via one or more hidden intermediate layers of neurons according to the predetermined formulation of the identified DEM model.

17. The system of claim 16, the one or more processors further configured to validate the trained neural network structure through one or more virtual test iterations with respect to simulated mechanical behaviors for each layer, wherein validating the trained datasets comprises automated evaluation of results for the at least one virtual test iteration on a quantitative basis and a qualitative basis.

18. The system of claim 13, wherein the industrial process being simulated corresponds to one or more components of a work machine interacting with the one or more agricultural materials.

19. The system of claim 18, wherein the output signals are provided as inputs to a model associated with virtual design of the one or more work machine components for working and/or storing the one or more agricultural materials.

20. The system of claim 18, wherein the outputs are provided as inputs to a model associated with planning and/or control of operations for the one or more work machine components in a worksite comprising the one or more agricultural materials.
